(19) United States
(12) Patent Application Publication
(10) Pub. No.: US 2007/0105300 A1
(43) Pub. Date: May 10, 2007

(54) Semiconductor substrate and method for manufacturing semiconductor device

(76) Inventor: Wan Gi Lee, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/595,641

(22) Filed: Nov. 8, 2006

(30) Foreign Application Priority Data
Nov. 8, 2005 (KR) 10-2005-0106563

(51) Int. Cl. H01L 21/8238; H01L 29/80

(52) U.S. Cl. 438/202; 257/274

(57) ABSTRACT

A semiconductor substrate and a method for manufacturing a semiconductor device are provided. A method for manufacturing a BiCMOS semiconductor device is capable of preventing the generation of a block defect causing particle source in the process of forming a DUF nitride layer for protecting a rear surface of a silicon wafer. The method for manufacturing a BiCMOS semiconductor device includes the steps of forming an oxide layer having a thickness of 500 Å or more on an upper surface, a lateral surface, and a rear surface of a silicon substrate, forming a nitride layer on the rear surface of the silicon substrate by depositing a nitride layer on the oxide layer and performing a blanket etching process with respect to the nitride layer, and forming a diffusion under film (DUF) area on the upper surface of the silicon substrate.

### RELATED APPLICATION

This application claims the benefit under 35 U.S.C. §119(e) of Korean Patent Application Number 10-2005-0106563 filed Nov. 8, 2005, which is incorporated herein by reference in its entirety.

### FIELD OF THE INVENTION

The present invention relates to a semiconductor device. More particularly, the present invention relates to a semiconductor substrate and a method for manufacturing a BiCMOS semiconductor device capable of preventing a particle source from being created on a rear surface of a silicon wafer.

### BACKGROUND OF THE INVENTION

A bipolar-complementary metal oxide silicon (BiCMOS) transistor has the advantages of incorporating both a CMOS transistor and a Bipolar transistor. The BiCMOS transistor includes a CMOS transistor and a Bipolar transistor formed on a single substrate, such that the BiCMOS transistor incorporates characteristics of high-speed operation, lower power consumption, and high precision. In addition, the BiCMOS transistor is suitable for high speed very large scale integration (VLSI) and is generally used for cache memory.

In a BiCMOS transistor, a CMOS transistor having NMOS and PMOS elements is integrated on a portion of a chip area of a wafer, and a Bipolar transistor having an emitter, a base, and a collector is formed on another portion of the chip area. Here, the CMOS transistor and the Bipolar transistor are simultaneously formed on the chip area.

When a CMOS transistor device or a BiCMOS transistor device is manufactured, the number of particles generated during a metal process is significantly different because of the structural differences and the back end of line (BEOL) processes of the CMOS transistor device and the BiCMOS transistor device.

If particles generated during the metal process land on a metal line, the yield rate may be reduced. Accordingly, many efforts to prevent the reduction of the yield rate caused by the particles have been made.

In order to prevent particles from being generated from a rear surface of a silicon wafer, the manufacturing process for the BiCMOS transistor includes a process of forming a diffusion under film (DUF) nitride layer on the rear surface of the silicon wafer.

Hereinafter, a conventional method of manufacturing a semiconductor device will be described with reference to accompanying drawings.

In addition, the relationship of metal defects generated in depositing and etching processes for a metal layer will be described. In particular, defects r elated to the etching equipment, the metal etching recipe, and processes performed prior to the etching step for a conventional BiCMOS product will be described.

FIGS. 1A to 1C are photographic views showing a typical defect map and block defects after etching a metal layer through the conventional method for manufacturing a BiCMOS semiconductor device.

FIG. 1A shows a typical defect map for a conventional BiCMOS product after a step of etching a first metal layer. Referring to FIG. 1A, the block defects mostly occur at the edges of the wafer. Here, as shown in FIGS. 1B and 1C, the size of the defect may be about 0.5 μm to about 3 μm.

The relationship of metal defects relative to the metal etching recipe and the etching equipment is described in reference to FIGS. 2A and 2B.

FIGS. 2A and 2B show a comparison of the number of block defects in a CMOS product with an A07S BiCMOS product employing the same metal etching recipe. As shown in FIGS. 2A and 2B, a greater number of block defects occur in the BiCMOS product (see FIG. 2B) as compared with the CMOS product (see FIG. 2A). Such a result signifies that a greater number of defects may occur due to the structural difference between the CMOS product and the BiCMOS product, rather than a difference of the metal etching recipe for the CMOS product and the BiCMOS product.

In addition, FIGS. 3A and 3B show the experimental result of particle generation and the analysis result of an Energy Dispersion Spectrometer (EDS) for a conventional A07S wafer having a metal layer pattern.

The experiment was performed by etching a wafer of the A07S product having a metal pattern for eight seconds to determine whether or not source particles of block defects were generated. As shown in FIGS. 3A and 3B, particles were generated. Here, silicon and oxide were detected in the particles when analyzing the particle components. Silicon oxide based materials were not used in the metal etching equipment employed for the experiment, so the silicon and the oxide were not generated from the etching equipment. Rather, it must be concluded that the silicon and oxide were generated from source particles of the wafer in a previous process step.

The relationship of the metal defect relative to a back end of line (BEOL) process is described below.

In order to determine the relationship of the metal defect relative to the BEOL process, a shortloop wafer was formed on a bare silicon (Si) wafer.

A split test was performed with respect to main process steps performed before the metal etching process, but there appeared to be no special difference according to conditions. In particular, block defects existing in the conventional A07S product were not generated in the test wafer, that is, in the bare Si wafer. More detail regarding the split test is described in reference to FIGS. 4 to 6.

Accordingly, particles and metal defects may be generated in a front end of line (FEOL) process rather than the BEOL process, and the generation of the particles and the metal defects may relate to the shape of a wafer.

In addition, when a metal layer of the A07S product is patterned, the block defects are generated after a metal etching process even if a wafer edge is fully covered with a photoresist film. This means that particles are generated from a rear surface of a wafer, rather than an upper surface of the wafer.

Thus, in order to determine the relationship between the FEOL process and the generation of particles, test wafers were manufactured under the same conditions as that of the comparative A07S product, and metal layers of a wafer formed with an epitaxial (EPI) layer, a wafer formed with LOCOS layer, and a wafer formed with a poly layer were etched under the baseline of the comparative A07S product. As a result, block defects are generated from all wafers. Accordingly, it can be understood that the problem occurs before and after forming the epitaxial layer, so a split test was performed with respect to previous and post processes for the epitaxial layer.

Hereinafter, conventional processes performed before forming the epitaxial layer on a silicon (Si) substrate will be briefly described.

First, an epitaxial layer is formed at a lower area before forming a moat active layer, and a DUF area, an N-type burred layer (NBL), and a well area are formed on the silicon substrate before or after forming the epitaxial layer.

FIG. 5 is a sectional view showing the structure of the DUF nitride layer subject to a conventional etching process.

Referring to FIG. 5, in order to form the DUF area on the silicon substrate, a first oxidation process is performed, thereby forming a DUF oxide layer 51 at an upper surface, a side, and a rear surface of the silicon wafer 50, and a DUF nitride layer 52 is deposited on the DUF oxide layer 51 and then a blanket etching process is performed with respect to the nitride layer 52.

In order to etch the DUF nitride layer 52, the blanket etching process is performed by applying HBr etchant onto the upper surface of the silicon (Si) wafer 50 under a high pressure condition without using a mask pattern.

After that, although it is not shown in figures, DUF patterning and etching processes are performed with respect to the resultant structure, thereby forming a DUF area on one area of the silicon wafer 50. Thereafter, the DUF oxide layer is removed, and then the epitaxial layer is formed.

Conventionally, ESC-type equipment without a clamp is used. Referring to FIG. 6, if He gas is fed onto the rear surface of the wafer in a state in which a wafer is picked up by the ESC-type equipment, plasma is unstably formed. Accordingly, He cooling is not performed with respect to the rear surface of the wafer.

In such a system, the edge of the wafer is exposed to the plasma during the etching process for the DUF nitride layer. Accordingly, if the nitride layer is completely etched, and an over-etching is performed beyond the end point, the nitride layer formed at the edge of the rear surface of the wafer gets impacted with the etching plasma, so that silicon formed on the rear surface of the wafer may be exposed. In addition, since the He cooling is not performed with respect to the rear surface of the wafer, more impact occurs at the rear surface of the wafer. When the nitride layer formed on the rear surface of the wafer is subject to the impact of the etching plasma so that silicon of the rear surface of the wafer is exposed as described above, silicon may grow on the rear surface of the wafer as well as the front surface of the wafer during formation of the epitaxial layer.

For the purpose of wafer backside cooling, He gas is fed between the wafer and the ESC under a pressure between 8 Torr and 12 Torr when the etching process is performed in a metal etching chamber. Such pressure is much higher than that of other semiconductor manufacturing processes using a chamber. When silicon (Si) has been grown on the edge of the rear surface of the wafer as described above, the silicon may be separated from the edge of the rear surface of the wafer due to the pressure of He gas provided onto the rear surface of the wafer. This silicon becomes particles during the metal etching process, thereby causing block defects.

FIG. 4 shows the result of the split test according to conditions before and after forming the epitaxial layer and the number of top block defects generated after etching a metal layer M1.

First and second wafers #01 and #02 were subject to the base line condition of the A07S product, and the remaining wafers were subject to the test condition.

According to the results, the number of block defects is remarkably reduced when the first metal layer is etched under the condition that the DUF oxide layer is formed with the thickness of 5000 Å or when the epitaxial layer depositing process is skipped.

FIG. 10 shows a scanning electron microscope (SEM) image of a rear surface of a wafer at the baseline condition before an epitaxial process. FIG. 11 shows a SEM image of the rear surface of a wafer after the epitaxial process and FIG. 12 shows a SEM image of the rear surface of a wafer when the epitaxial process is skipped. Referring to FIGS. 10-12, it can be seen that there is a difference at the edge area of the rear surfaces between the base line condition shown in FIG. 10 and split conditions shown in FIGS. 11 and 12.

Referring to FIG. 10, the protrusions formed on the baseline wafer were determined to be silicon through the ESD analysis result of the protrusions. It can be understood from the analysis result of FIGS. 11 and 12 that silicon does not grow on a rear surface of a wafer when the DUF oxide layer is excessively thick(FIG. 11), or when a depositing process for the epitaxial layer is skipped (FIG. 12). Accordingly, the block defects occurring after the metal etching step are strongly related to the state of the rear surface of the wafer of the conventional A07S product.

However, since a DUF oxide layer having the thickness of 5000 Å cannot in practice be deposited on the A07S product, it is necessary to select a suitable thickness for the DUF oxide layer.

As described above, block defects may occur in the metal etching process due to a variety of factors, and the source of the defects mainly relates to the metal etching recipe, the equipment, and the processes performed before the metal etching process.

Further, in the BiCMOS product, an epitaxial layer is grown below a moat active layer, and the process of growing the epitaxial layer is affected by the cleanness of the wafer. Before growing the epitaxial layer, if a DUF nitride layer (Si3N4) protecting the rear surface of the wafer is also etched during to the front-side nitride etching process, the epitaxial layer may grow from the end part of the rear surface of the silicon wafer. Such a phenomenon may cause the block defects in the subsequent process of etching a metal layer.

### SUMMARY OF THE INVENTION

Accordingly, an object of embodiments of the present invention is to provide a method for manufacturing a BiCMOS semiconductor device capable of preventing the generation of a particle source that causes block defects in the process of forming a DUF nitride layer for protecting a rear surface of a silicon wafer.

Another object of embodiments of the present invention is to provide a semiconductor substrate capable of preventing the generation of a particle source that causes block defects in the process of forming a DUF nitride layer for protecting a rear surface of a silicon wafer.

To achieve these objects and other advantages and in accordance with the purpose of the invention, as embodied and broadly described herein, there is provided a method for manufacturing a BiCMOS semiconductor device, including the steps of forming an oxide layer having a thickness of 500 Å or more on an upper surface, a lateral surface, and a rear surface of a silicon substrate, forming a nitride layer on the rear surface of the silicon substrate by depositing a nitride layer on the oxide layer and performing a blanket etching process with respect to the nitride layer, and forming a diffusion under film (DUF) area on the upper surface of the silicon substrate.

According to another aspect of the present invention, there is provided a disk shaped silicon semiconductor substrate having an upper surface, a lateral surface, and a rear surface opposite to the upper surface, the semiconductor substrate incorporating: an oxide layer covering the upper surface, the lateral surface, and the rear surface, where the oxide layer is formed to a first thickness on the upper surface and a second thickness thicker than the first thickness on the lateral surface and the rear surface; and a nitride layer formed on the oxide layer on the rear surface.

### BRIEF DESCRIPTION OF THE DRAWINGS

The above and other objects, features and advantages of the present invention will be more apparent from the following detailed description taken in conjunction with the accompanying drawings, in which:

FIGS. 1A to 1C are photographic views showing a typical defect map and typical block defects after etching a metal layer through the conventional method for manufacturing a semiconductor device;

FIGS. 2A and 2B are graphs showing the number of block defects occurring in a CMOS product and a conventional A07S product which employ the same metal etching process;

FIGS. 3A and 3B show the experimental result of particle generation and the EDS spectrum for a wafer having a metal layer pattern;

FIG. 4 shows a split test result according to conditions before and after an epitaxial process and the number of block defects generated after an etching process for a metal layer;

FIG. 5 is a sectional view showing the structure of the DUF nitride layer subject to a conventional etching process;

FIG. 6 is a schematic view showing the generation of particles during an etching process in a metal layer etching chamber;

FIG. 7 is a table showing the result of a split test depending on the thickness of diffusion under film (DUF) oxide layer according to an embodiment of the present invention;

FIGS. 8 and 9 are photographical views showing a rear surface of a wafer after forming a defect map and an epitaxial layer when the thickness of DUF oxide layer is 1000 Å;

FIGS. 10 to 12 are views showing the rear surface of a wafer before and after an epitaxial process and after a split process; and

FIGS. 13A to 13E are sectional views showing a method for manufacturing a semiconductor device according to an embodiment of the present invention.

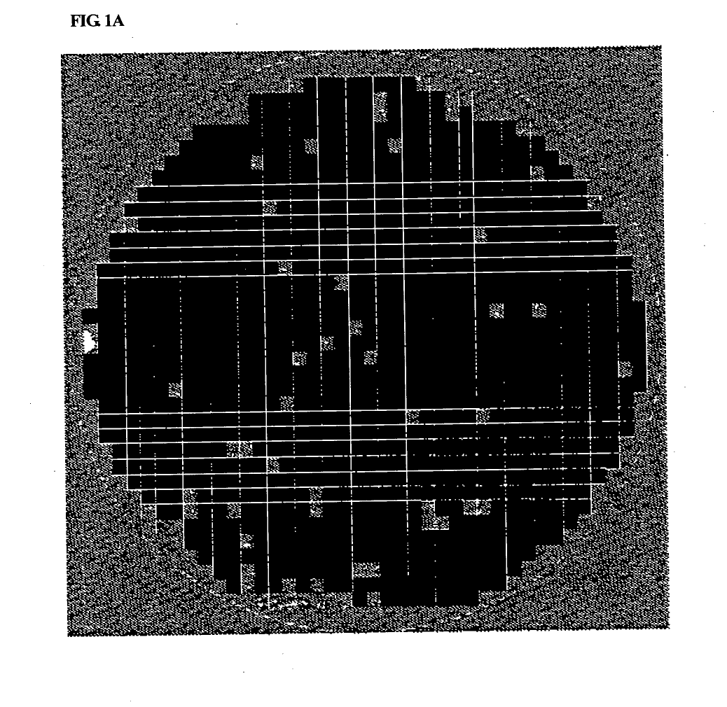

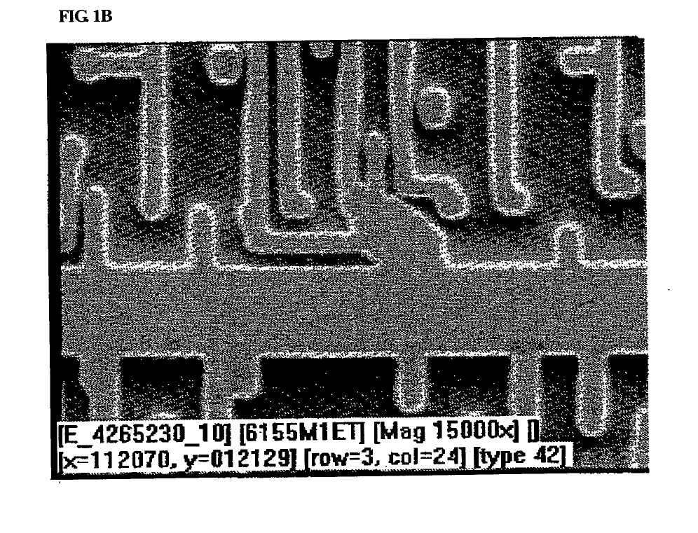

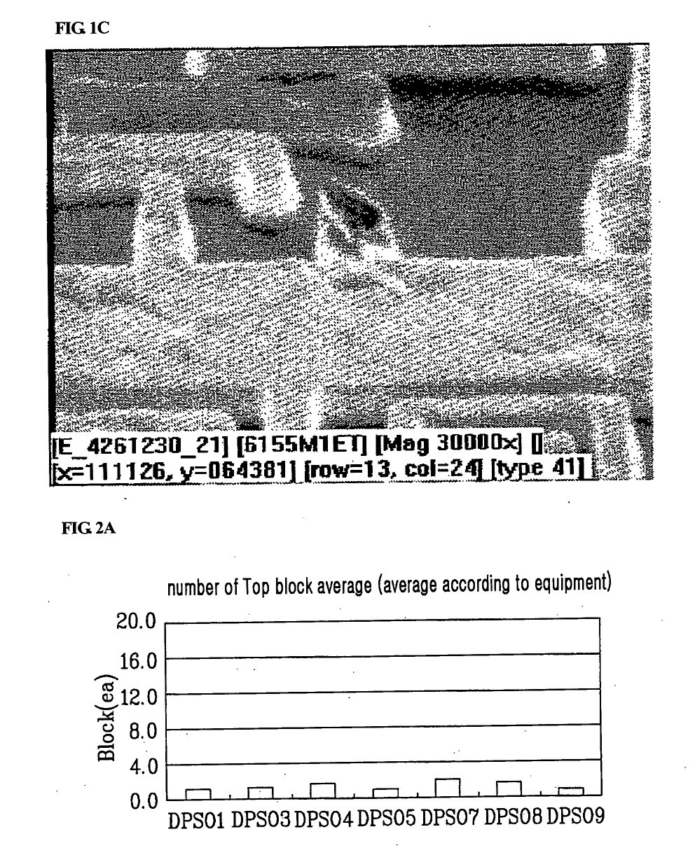

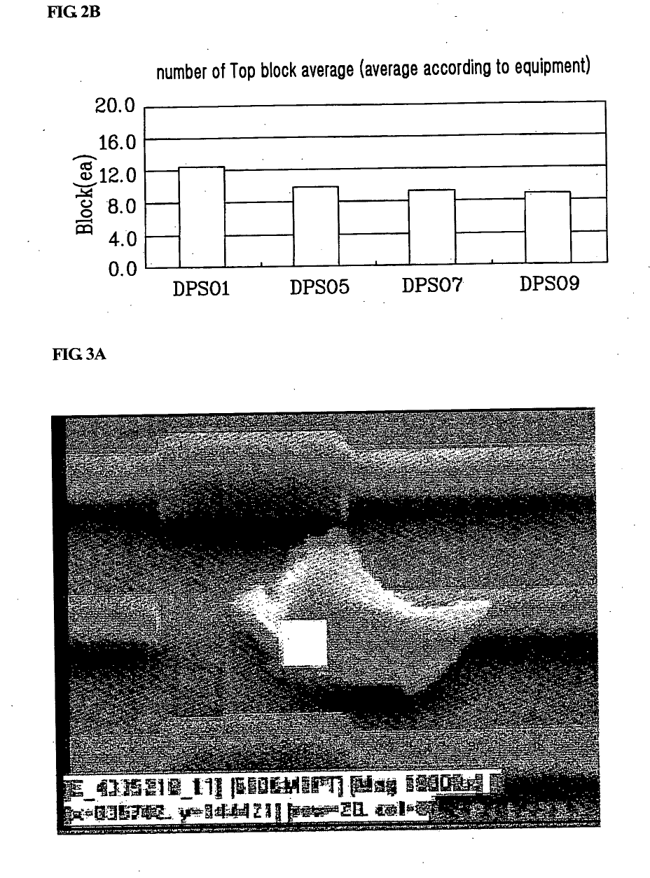

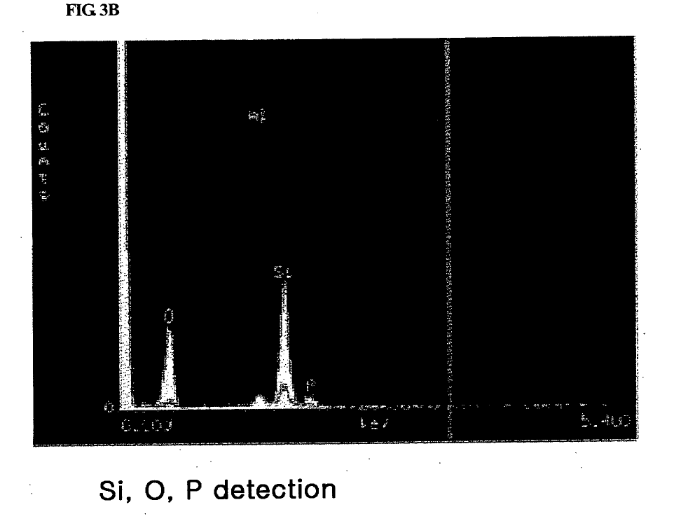

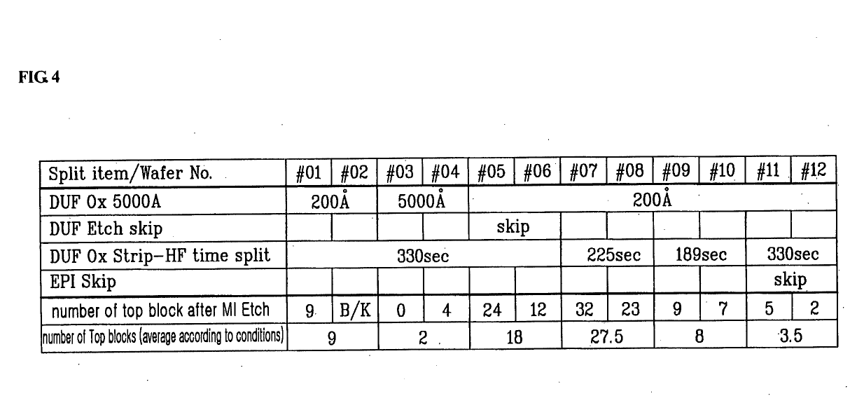

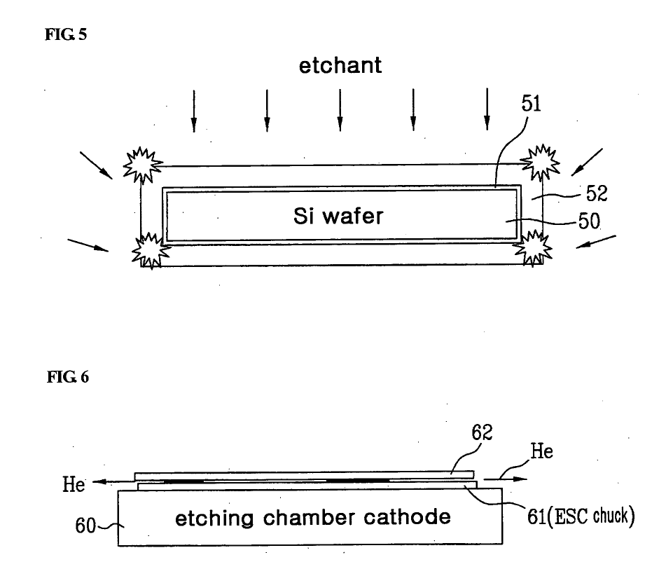

### DETAILED DESCRIPTION OF THE PREFERRED EMBODIMENTS

Hereinafter, a method for manufacturing a semiconductor device and a semiconductor substrate according to a preferred embodiment of the present invention will be described with respect to accompanying drawings.

According to an embodiment for manufacturing BiCMOS transistors, the generation of a particle source causing metal block defects in a metal layer etching process can be prevented. In addition, clamp-type equipment can be used in a front-side nitride etching process (DUF nitride etching process) for protecting a rear surface of a wafer. In a further embodiment, the thickness of the DUF oxide layer formed at a lower portion of a DUF nitride layer can be increased.

In other words, the present invention can provide a DUF oxide layer having a certain thickness and a nitride etching recipe suitable for forming a DUF area such that a defect source causing block defects during the metal layer etching process cannot be created before the forming of an epitaxial layer.

Although not shown in the figures, a DUF area, an N-type buried layer area, and a well area can be formed on a silicon substrate before and/or after forming the epitaxial layer.

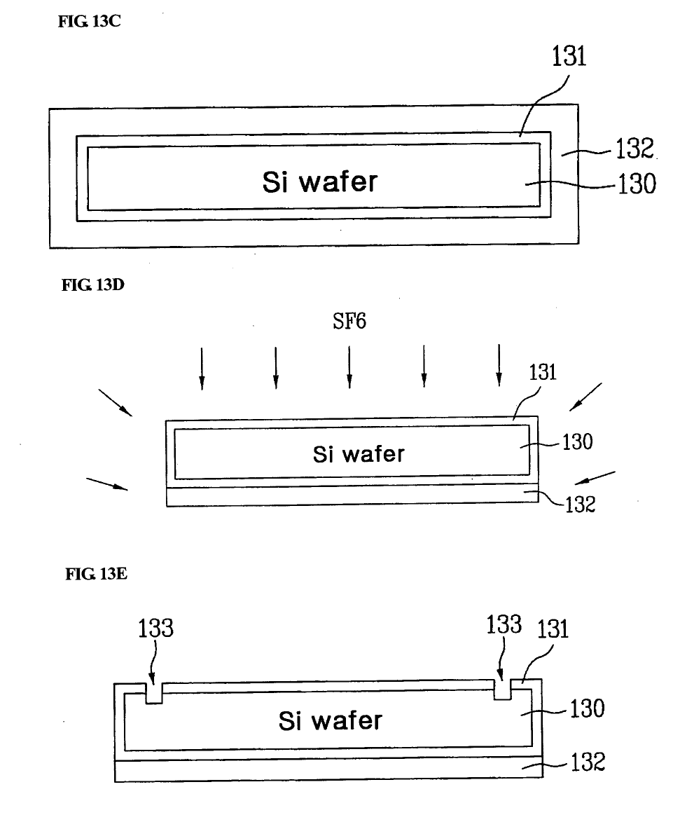

Hereinafter, a process for forming the DUF area according to the present invention will be described with reference to FIGS. 13A-13E.

First, referring to FIGS. 13A and 13B, a first oxidation process can be performed in order to form the DUF area on the silicon wafer 130, thereby forming a DUF oxide layer 131 at upper, lateral, and rear surfaces of the silicon wafer 130. In an embodiment, the DUF oxide layer can be formed to a thickness of 500 Å or more. In a specific embodiment, the oxide layer 131 can be formed with the thickness of about 500 Å to about 1000 Å.

The DUF oxide layer 131 formed with the thickness in the range between about 500 Å and about 1000 Å can effectively prevent plasma from penetrating into an edge of the rear surface of the silicon wafer 130 as compared with a DUF oxide layer formed with the thickness of about 200 Å.

Next, as shown in FIG. 13C, a DUF nitride layer 132 can be deposited on the DUF oxide layer 131.

Thereafter, referring to FIG. 13D, the nitride layer 132 can be etched through a blanket etching process using a ring-type clamp, such as a chuck, or clamp-type equipment (not shown) such as a finger-type clamp, in order to protect an edge area of the silicon wafer 130. In a specific embodiment, the rear surface of the wafer can be protected from the etching process such that the DUF nitride layer 132 remains on the rear surface of the wafer.

Next, referring to FIG. 13E, predetermined portions 133 of the DUF oxide layer 131 and the silicon wafer 130 can be etched through a photolithography process using a photo mask (not shown). In one embodiment, the DUF area 133 can serve as an align mask in subsequent ion implantation and patterning processes. The DUF area 133 can be prepared in the form of a groove at a predetermined portion of the edge of the silicon wafer 130.

Then, although it is not shown in figures, after removing the DUF oxide layer such that the silicon wafer 130 is exposed, an epitaxial layer can be grown on the exposed silicon wafer, and then a moat active layer can be formed on the epitaxial layer.

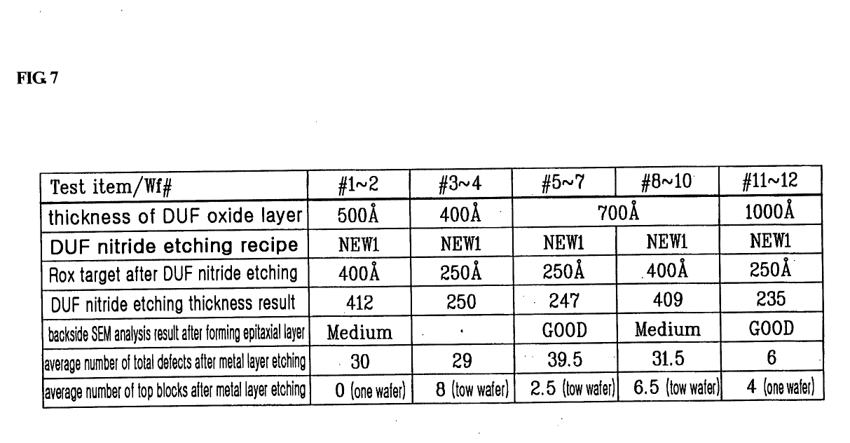

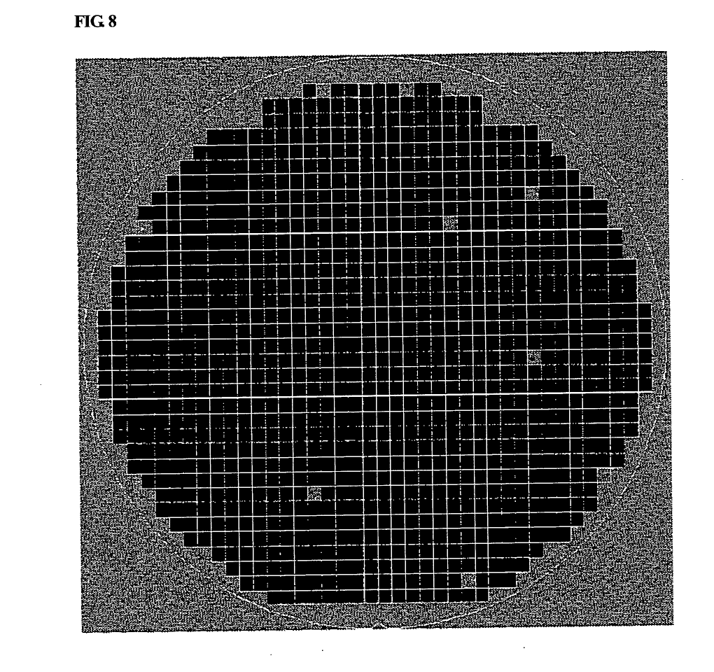

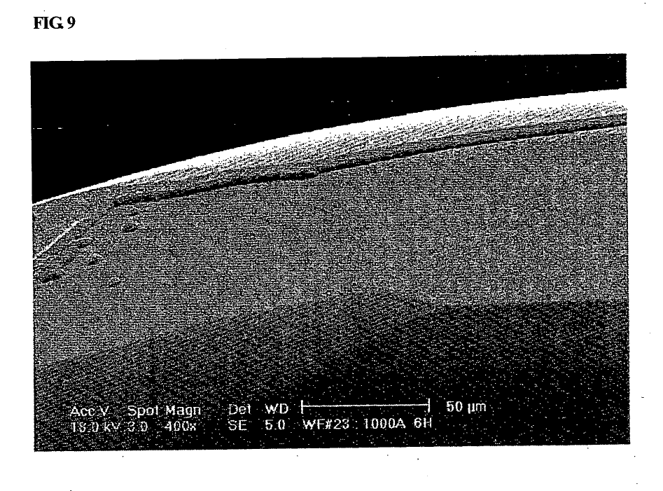

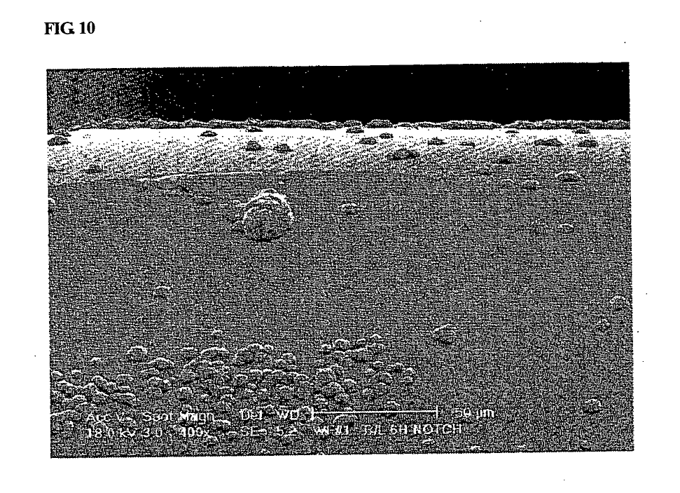

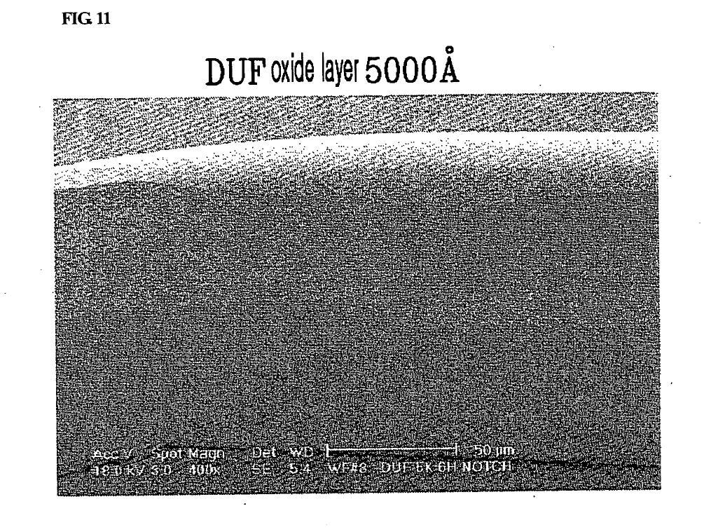

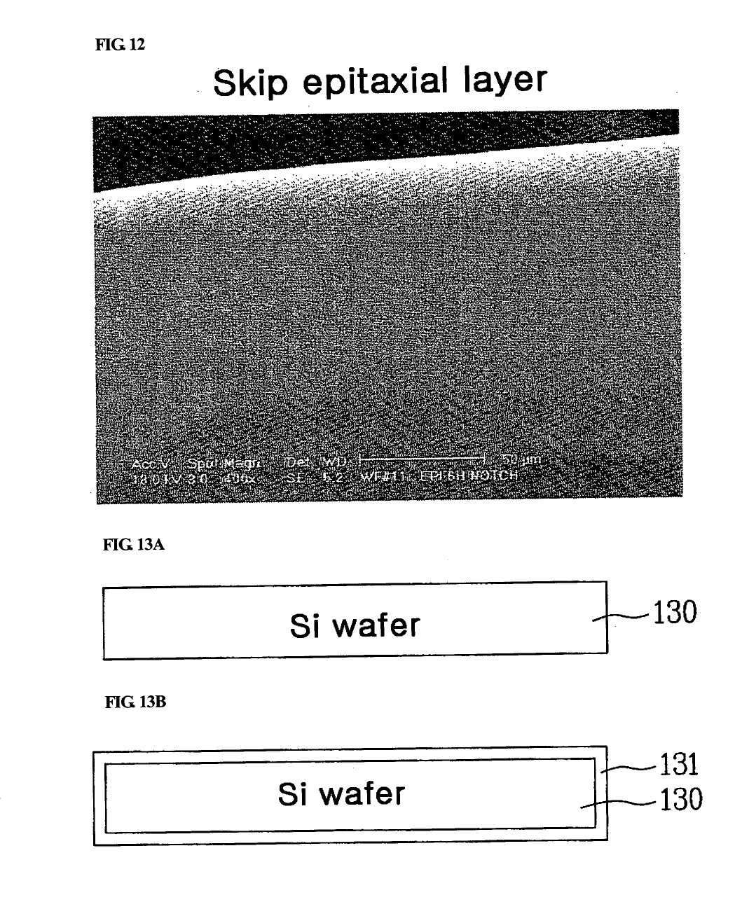

FIG. 7 shows the result of a split test for processes depending on the thickness of the DUF oxide layer according to embodiments of the present invention, where the DUF oxide layer is formed between thicknesses of 400 Å and 1000 Å. In addition, FIGS. 8 and 9 are photographical views showing a defect map and a rear surface of a wafer after forming an epitaxial layer when the thickness of the DUF oxide layer is 1000 Å.

In many embodiments of the subject invention, the DUF oxide layer 131 can be deposited with the thickness of about 500 Å to about 1000 Å. As shown in FIG. 7, the DUF oxide layer 131 having the thickness of 500 Å or more can reduce the number of block defects generated from the first metal layer as compared with the DUF oxide layer having the thickness of 200 Å under a baseline condition. Among other things, the DUF oxide layer 131 having the thickness 1000 Å brings the least number of total defects after the etching process for the first metal layer has been finished.

When considering that silicon grown from the rear surface of the silicon wafer 130 not only can cause block defects of the first metal layer, but can also generate particles during aluminum (Al) sputtering or CVD process, superior defect data (defect map) and a superior state of the rear surface of the wafer can be obtained when the DUF oxide layer 131 has the thickness of 1000 Å as shown in FIGS. 8 and 9.

In a further embodiment, an etching process for the DUF nitride layer can be performed under HBr gas base while applying high pressure. However, if the blanket etching process is performed with respect to the DUF nitride layer under the high pressure condition as described above, a predetermined amount of etching may occur at the rear surface of the silicon wafer.

Therefore, according to embodiments of the present invention, the DUF nitride layer 132 can be etched under a SF6 gas base while applying low pressure of 250 mTorr or less.

According to another embodiment of the present invention, in the DUF oxide layer 131 formed on the wafer, the thickness of the DUF oxide layer 131 formed on the upper surface of the wafer may differ from the thickness of the DUF oxide layer 131 formed on lateral and rear surfaces of the wafer.

For example, the DUF oxide layer 131 formed on the upper surface of the wafer may have a first thickness, and the DUF oxide layer 131 formed on the lateral and rear surfaces of the wafer may have a second thickness greater than the first thickness. According to an embodiment of the present invention, the second thickness is preferably in the range between about 500 Å and about 1000 Å.

As described above, a method for manufacturing a semiconductor device according to the present invention has following advantages.

First, embodiments of the present invention can incorporate clamp-type equipment in the process of etching a nitride layer, so the nitride layer is prevented from being damaged at the edge of a rear surface of a wafer, so that it is possible to prevent silicon (Si) from growing on the rear surface of the wafer and to prevent the generation of block defects in the following metal layer etching process.

Second, embodiments of the present invention can provide an oxide layer having the thickness of 500 Å or more, so plasma is prevented from penetrating into the edge of the rear surface of the wafer, so that it is possible to prevent a particle source from being created on the rear surface of the wafer.

Those skilled in the art will appreciate that various modifications, additions and substitutions are possible, without departing from the scope and spirit of the invention

Accordingly, the scope of the present invention is not limited to the embodiments, but defined by accompanying claims.

I claim:

1. A method for manufacturing a BiCMOS semiconductor device comprising:
forming an oxide layer having a thickness of 500 Å or more on an upper surface, a lateral surface, and a rear surface of a silicon substrate;
forming a nitride layer on the rear surface of the silicon substrate by depositing a nitride layer on the oxide layer and performing a blanket etching process with respect to the nitride layer; and
forming a diffusion under film (DUF) area on the upper surface of the silicon substrate.

2. The method according to claim 1, wherein the oxide layer has a thickness between 500 Å and 1000 Å.

3. The method according to claim 1, wherein performing a blanket etching process comprises etching the nitride layer using SF6 gas while applying a pressure of 250 mTorr or less.

4. The method according to claim 1, further comprising clamping the silicon substrate using a ring-type clamp or a finger-type clamp in order to protect an edge area of the silicon substrate during performing the blanket etching process.

5. The method according to claim 1, wherein depositing the nitride layer on the oxide layer comprises forming the nitride layer on the upper surface, the lateral surface, and the rear surface of the silicon substrate.

6. The method according to claim 1, wherein forming the DUF area comprises performing a photolithography process with respect to the oxide layer formed on the upper surface of the silicon substrate and the silicon substrate using a photomask.

7. The method according to 1, wherein the oxide layer formed on the upper surface of the silicon substrate has a first thickness, and the oxide layer formed on the lateral and rear surfaces of the silicon substrate has a second thickness thicker than the first thickness.

8. The method according to claim 7, wherein the second thickness is between 500 Å and 1000 Å.

9. A semiconductor substrate comprising:
a disk shaped silicon body having an upper surface, a lateral surface, and a rear surface opposite to the upper surface;
an oxide layer on the upper surface, the lateral surface, and the rear surface of the silicon body, wherein the oxide layer on the upper surface has a first thickness and the oxide layer on the lateral surface and the rear surface has a second thickness thicker than the first thickness; and
a nitride layer formed on the rear surface of the silicon body.

10. The semiconductor substrate according to claim 9, wherein the second thickness is between 500 Å and 1000 Å such that silicon is prevented from growing on the rear surface of the silicon body.

11. The semiconductor substrate according to claim 9, wherein a diffusion under film (DUF) area is formed on the upper surface of the silicon body.

12. The semiconductor substrate according to claim 9, wherein a plurality of chip areas are formed on the upper surface of the silicon body, and a CMOS transistor and a bipolar transistor are formed in each of the plurality of chip areas.
